(19) United States
(12) Patent Application Publication
(10) Pub. No.: US 2011/0116240 A1
(43) Pub. Date: May 19, 2011

(54) ROTATABLE POSITIONING PIVOT STRUCTURE AND DRIVER HAVING THE SAME

(76) Inventors: Yi-Chen WANG, Taoyuan Shien (TW); Mi-Tien Tsai, Taoyuan Shien (TW); Ming-Hua Huang, Taoyuan Shien (TW)

(21) Appl. No.: 12/619,755

(22) Filed: Nov. 17, 2009

(51) Int. Cl. H05K 7/00

(52) U.S. Cl. 361/728

(57) ABSTRACT

In a rotatable positioning pivot structure and a driver having the pivot structure, the pivot structure includes a casing and a cover movably assembled with the casing. The casing is provided with an opening. One side of the opening is provided with a positioning shaft. The positioning shaft is provided with a positioning portion. One side of the cover is provided with an elastic piece. The elastic piece is provided with a through trough, and an elastic arm is formed in the through trough. The positioning shaft of the casing penetrates the through trough of the cover and is located inside the elastic arm. The inside of the elastic arm is provided with at least one positioning slot to be engaged with the positioning portion of the positioning shaft. With the above arrangement, the rotation of the cover can be positioned. Further, the pivot structure is arranged in the driver.

### BACKGROUND OF THE INVENTION

1. Field of the Invention

The present invention relates to a pivot structure, and in particular to a pivot structure having a positioning effect.

2. Description of Prior Art

Usually, a driver is used to control the operation of a motor or an electronic device, thereby achieving the required output current or rotating speed.

The conventional driver has a circuit board on which control chips, resistors, capacitors and other electronic elements are arranged. The circuit board is further provided with a plurality of connecting terminals. Electric leads of the motor or the electronic device are electrically connected to the connecting terminals respectively, so that the operation of the motor or the electronic device can be controlled by the circuit board.

In order to prevent the circuit board of the driver from suffering damage due to humidity or dust, the driver is usually sealed by a box. Since the connecting terminals of the driver have to be exposed to the outside of the box for electrical connection, the connecting terminals are still prone to be rusted by humidity or covered by dust easily. Further, a user may touch the displayed connecting terminals carelessly to cause the breakdown of the driver.

Thus, a movable terminal cover is provided over the connecting terminals. After the cover is opened, the terminals are ready for use. After finishing the electrical connection, the terminal cover is closed on the box. Although this solution really overcomes the above-mentioned problem, the terminal cover of the driver can be only rotated but not positioned in predetermined angles. As a result, the cover may fall on the connecting terminals unintentionally, which makes the user inconvenient in use. Although another terminal cover having a positioning shaft is proposed, its construction is so complicated that the user cannot use it well and sometimes makes it to suffer damage carelessly.

Therefore, it is an important issue for the present Inventor to solve the above-mentioned problems.

### SUMMARY OF THE INVENTION

The present invention is to provide a driver having a rotatable positioning pivot structure, whereby a cover of the driver can be positioned easily after being opened, and the electrical connection to the connecting terminals in a casing can be completed easily.

The present invention is to provide a driver having a rotatable positioning pivot structure, which can be operated easily by a user.

The present invention is to provide a driver having a rotatable positioning pivot structure, which includes a casing, a circuit board and a cover. The casing is provided with an accommodating space and an opening in communication with the accommodating space. The casing is provided on one side of the opening with a positioning shaft. The positioning shaft is provided with a positioning portion. The circuit board is received in the accommodating space. The circuit board is provided with a plurality of connecting terminals. The connecting terminals are displayed in the opening. The cover is movably assembled in the opening of the casing. One side of the cover is provided with an elastic piece. The elastic piece is provided with a through trough, and an elastic arm is formed in the through trough. The positioning shaft of the casing penetrates the through trough of the cover and is located inside the elastic arm. The inside of the elastic arm is provided with at least one positioning slot for engaging with the positioning portion of the positioning shaft.

The present invention is to provide a rotatable positioning pivot structure. A casing is provided therein with a positioning shaft. A cover assembled with the casing is provided with a through trough and an elastic arm. The positioning shaft penetrates the inside of the elastic arm, so that the positioning shaft can be positioned.

The present invention is to provide a rotatable positioning pivot structure, which can be assembled easily.

The present invention is to provide a rotatable positioning pivot structure, which includes a casing and a cover. The casing is provided with an opening. The casing is provided on one side of the opening with a positioning shaft. The positioning shaft is provided with a positioning portion. The cover is movably assembled in the opening of the casing. One side of the cover is provided with an elastic piece. The elastic piece is provided with a through trough, and an elastic arm is formed in the through trough. The positioning shaft of the casing penetrates the through trough of the cover and is located inside the elastic arm. The inside of the elastic arm is provided with at least one positioning trough for engaging with the positioning portion of the positioning shaft.

In comparison with prior art, the rotatable positioning pivot structure of the present invention is provided with the positioning shaft and the rib in the casing. Further, the cover is provided with the through trough and the elastic piece. The positioning shaft is positioned in the through trough in such a manner that the rib presses the abutting portion to cause an elastic deformation. With the elastic piece abutting the rib, the frictional force for positioning can be increased. Further, the pivot structure of the present invention is simple in construction. The cover can be assembled with the casing easily. Thus, the practicability and the convenience of the present invention can be increased.

### BRIEF DESCRIPTION OF THE DRAWINGS

FIG. 1 is an exploded perspective view showing the rotatable positioning pivot structure of the present invention;

FIG. 2 is an enlarged view showing the portion A of FIG. 1;

FIG. 3 is an enlarged view showing the portion B of FIG. 1;

FIG. 4 is a view taken from another side of FIG. 3;

FIG. 5 is an enlarged view showing the portion C of FIG. 1;

FIG. 6 is an assembled perspective view showing the rotatable positioning pivot structure of the present invention;

FIG. 7 is a cross-sectional view taken along the line 7-7 in FIG. 6;

FIG. 8 is a cross-sectional view taken along the line 8-8 in FIG. 7;

FIG. 9 is a cross-sectional view showing the rotatable positioning pivot structure of the present invention forms a 45-degree angle with respect to the opening;

FIG. 10 is another cross-sectional view showing the rotatable positioning pivot structure of the present invention forms a 45-degree angle with respect to the opening;

FIG. 11 is a cross-sectional view showing the rotatable positioning pivot structure of the present invention forms a 90-degree angle with respect to the opening;

FIG. 12 is another cross-sectional view showing the rotatable positioning pivot structure of the present invention forms a 90-degree angle with respect to the opening;

FIG. 13 is a schematic view showing the application of the rotatable positioning pivot structure of the present invention.

### DETAILED DESCRIPTION OF THE INVENTION

The characteristics and technical contents of the present invention will be described with reference to the accompanying drawings. However, the drawings are illustrative only but not used to limit the present invention.

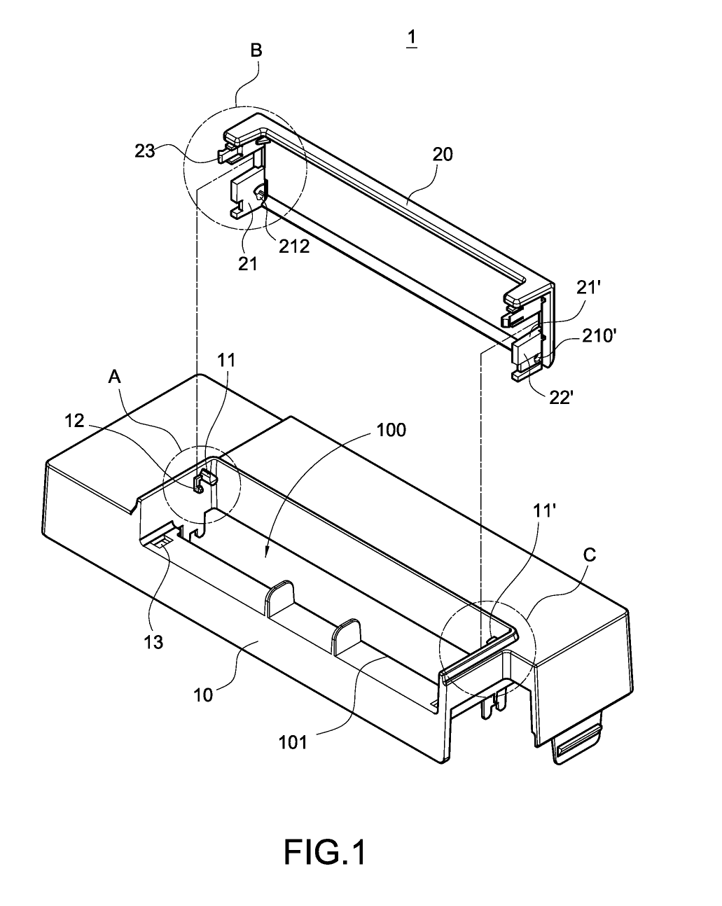

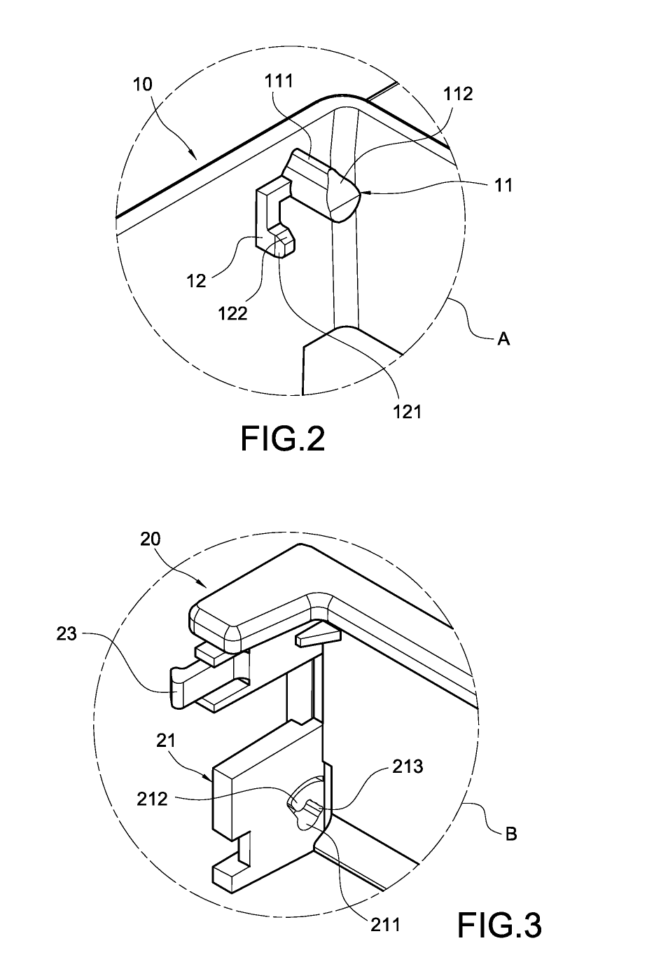

Please refer to FIGS. 1 to 6. FIG. 1 is an exploded perspective view showing the rotatable positioning pivot structure of the present invention. FIGS. 2 to 4 are enlarged views showing a portion of the present invention respectively. FIGS. 5 and 6 are assembled perspective views of the present invention. The pivot structure 1 of the present invention includes a casing 10 and a cover 20. With the pivot structure 1, the cover 20 is movably assembled with the casing 10, and the rotation of the cover 20 can be positioned easily.

Please refer to FIG. 2, which is an enlarged view showing the portion A of FIG. 1. The casing 10 is provided with an opening 101 and an accommodating space 100 in communication with the opening 101. The casing 10 is provided on one side of the opening 101 with a positioning shaft 11. The positioning shaft 11 extends to form a narrowed end. The top surface of the narrowed end is formed into a positioning portion 111. The distal end of the positioning shaft 11 is provided with a chamfer 112. Further, the casing 10 is provided with a rib 12 adjacent to the positioning shaft 11. In the present embodiment, the cross section of the rib 12 is formed into an L shape. The distal end of the rib 12 is formed with a protrusion 121 that also has a chamfer 122.

Please refer to FIG. 3, which is an enlarged view showing the portion B of FIG. 1. The cover 20 is movably assembled in the opening 101 of the casing 10. One side of the cover 20 is provided with an elastic piece 21 to correspond to the positioning shaft 11 of the casing 10. The elastic piece 21 is provided with a through trough 211. An elastic arm 212 is formed within the through trough 211. The positioning shaft 11 of the casing 10 penetrates the through trough 211 of the cover 20 and is located inside the elastic arm 212. The inside of the elastic arm 212 is provided with at least one positioning slot 213 for engaging with the positioning portion 111 of the positioning shaft 11.

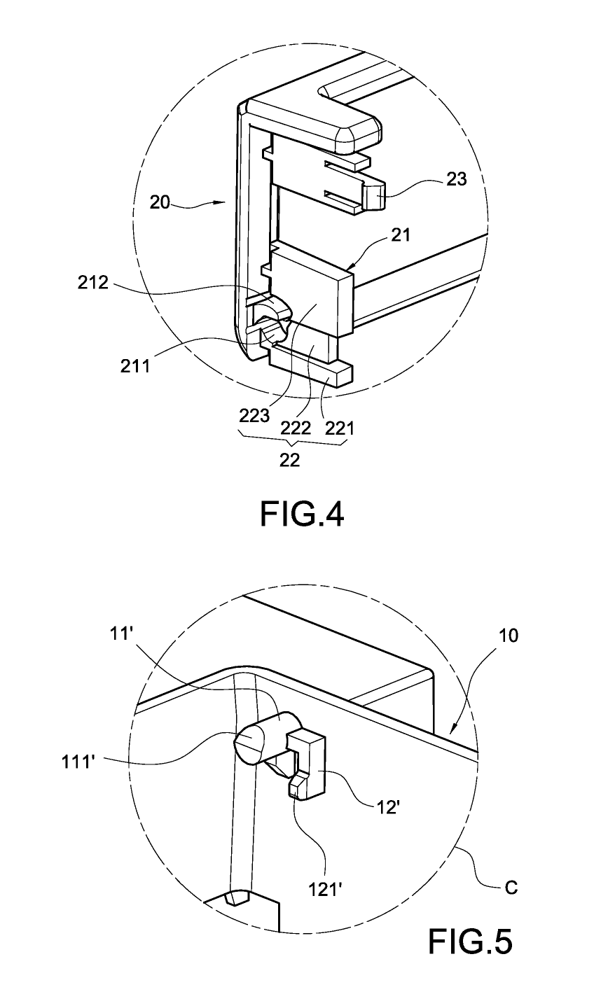

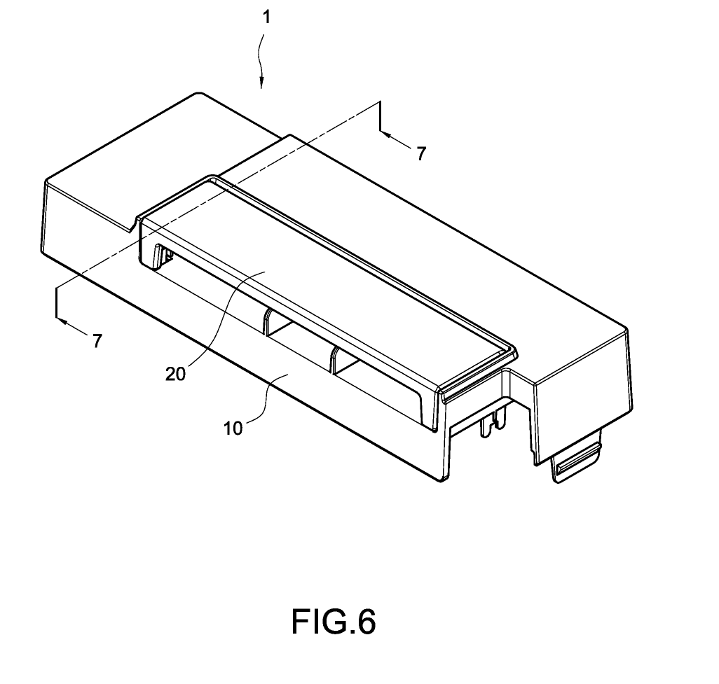

Please refer to FIG. 4, which is a view taken from another side of FIG. 3. The elastic piece 21 of the cover 20 is provided with an abutting portion 22 to correspond to the rib 12 of the cover 10. Thus, when the positioning shaft 11 of the casing 10 penetrates the through trough 211, the rib 12 will abut the abutting portion 22. The cross section of the abutting portion 22 is formed into a U shape. The height of both outside surfaces 221, 223 is larger than that of the intermediate surface 222. Further, the cover 20 is provided with a hook 23. The casing 10 is provided with a notch 13 (FIG. 1) corresponding to the hook 23. The hook 23 is engaged within the notch 13, so that the cover 20 can close the opening 101 of the casing 10.

Please refer to FIG. 5, which is an enlarged view showing the portion C of FIG. 1. In the present embodiment, the other side of the cover 20 is also provided with an elastic piece 21′. The elastic piece 21′ is provided with a shaft hole 210′ and an abutting portion 22′. The casing 10 is provided one the other side of the opening 101 with a shaft 11′ and a rib 12′. The shaft 11′ and the rib 12′ are provided with a chamfer 111′ and 121′ respectively. The shaft 11′ penetrates the shaft hole 210′, and the rib 12′ abuts the abutting portion 22′. Of course, the elastic piece 21′ and the shaft 11′ can have the same construction as that of the aforesaid elastic piece 21 and the positioning shaft 11 respectively.

Please refer to FIG. 6, which is an assembled perspective view showing the rotatable positioning pivot structure of the present invention. During the assembly of the pivot structure 1, since the distal ends of the positioning shaft 11, the ribs 12, 12′ and the shaft 11′ are provided with a chamfer respectively, the positioning shaft 11 and the shaft 11′ of the casing 10 can penetrate the through trough 211 and the shaft hole 210′ of the cover 20 respectively.

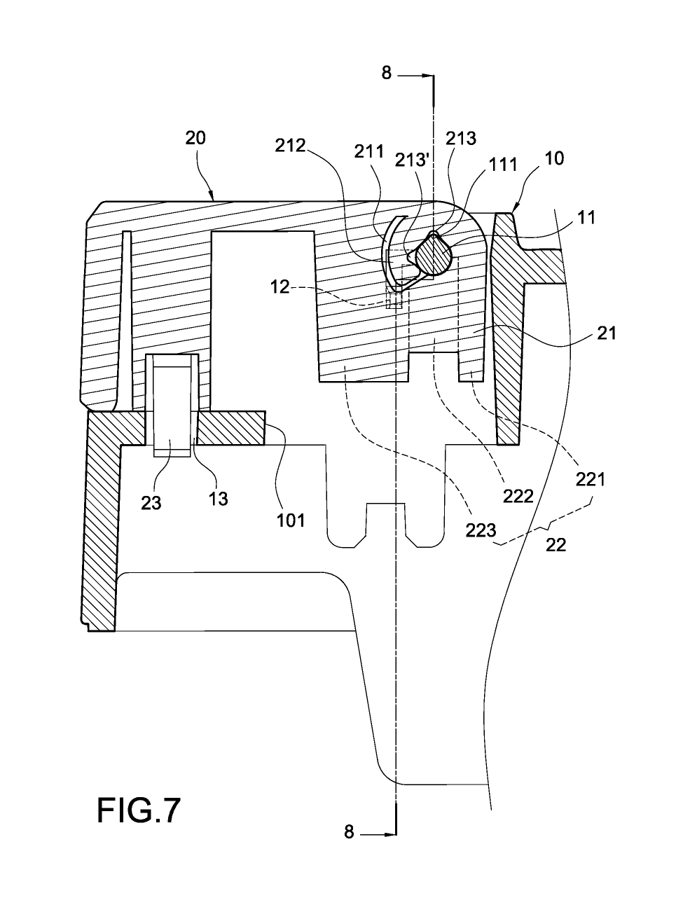

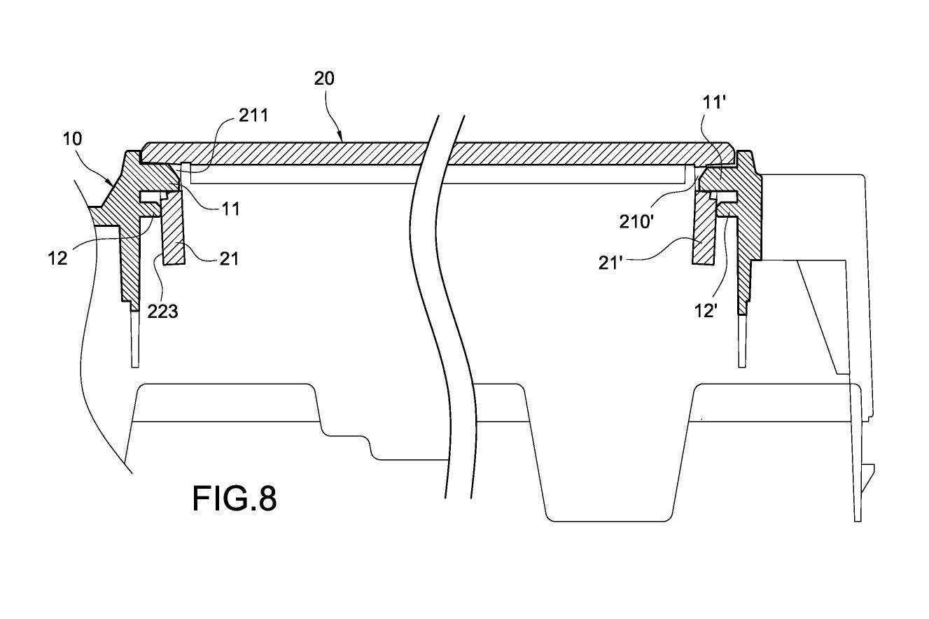

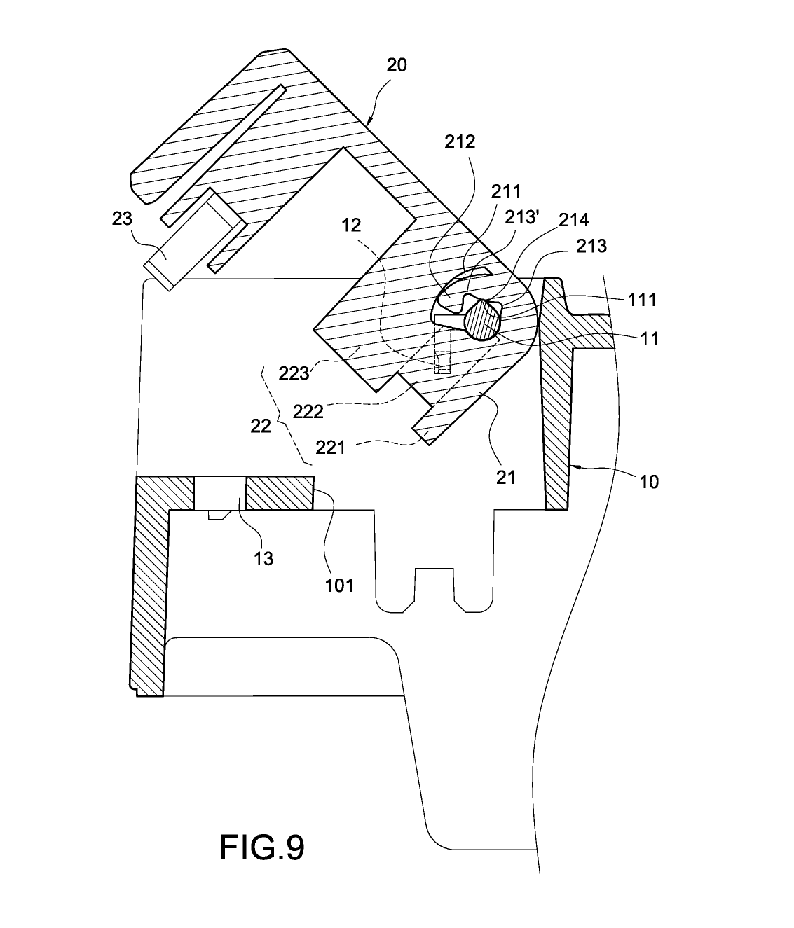

Please refer to FIGS. 7 and 8, which are cross-sectional views showing the rotatable positioning pivot structure of the present invention in a closed state. It can be seen that the hook 23 is engaged in the notch 13, the positioning shaft 11 is located inside the elastic arm 212, and the positioning portion 111 of the positioning shaft 11 is located in the positioning slot 213 of the through trough 211. In the present embodiment, two positioning slots 213, 213′ are provided. At this time, the rib 12 presses on the outside surface 223 (indicated by the dotted portion in FIG. 7) of the abutting portion 22, so that the elastic piece 21 is subjected to an elastic deformation to abut the outside surface 223. In this way, the frictional force for positioning can be increased.

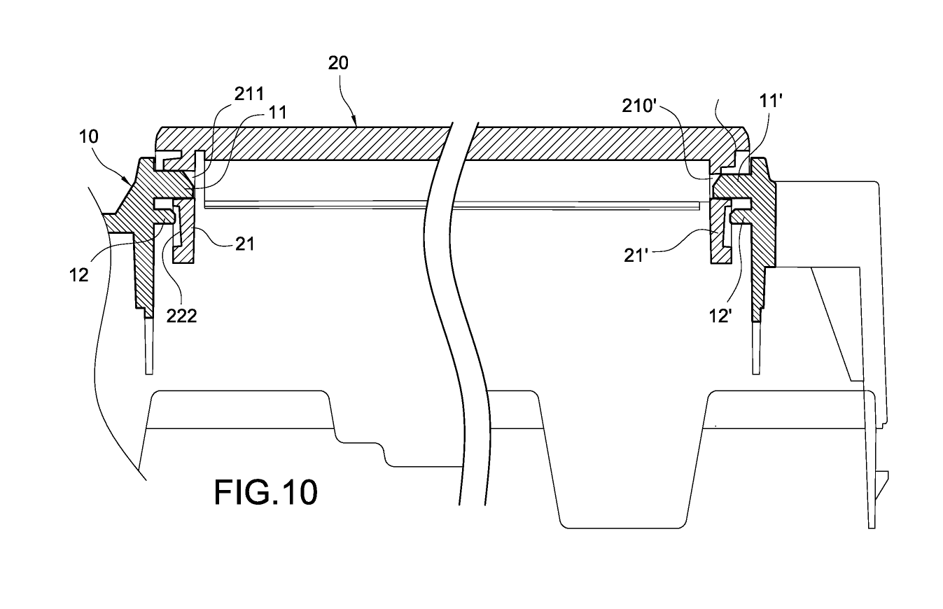

Please refer to FIGS. 9 and 10, which are cross-sectional views showing the rotatable positioning pivot structure 1 of the present invention forms an angle of 45 degrees with respect to the opening 101. When the cover 20 is opened to form a 45-degree angle with respect to the opening 101, the positioning portion 111 of the positioning shaft 11 abuts a raised surface 214 between the two positioning slots 213, 213′. The rib 12 is located on the intermediate surface 222 of the abutting portion 22 (indicated by the dotted portion in FIG. 9). At the same time, the positioning portion 111 of the positioning shaft 11 presses the raised surface 214, so that the elastic arm 212 is subjected to an elastic deformation to abut the positioning portion 111. In this way, the frictional force for positioning can be increased.

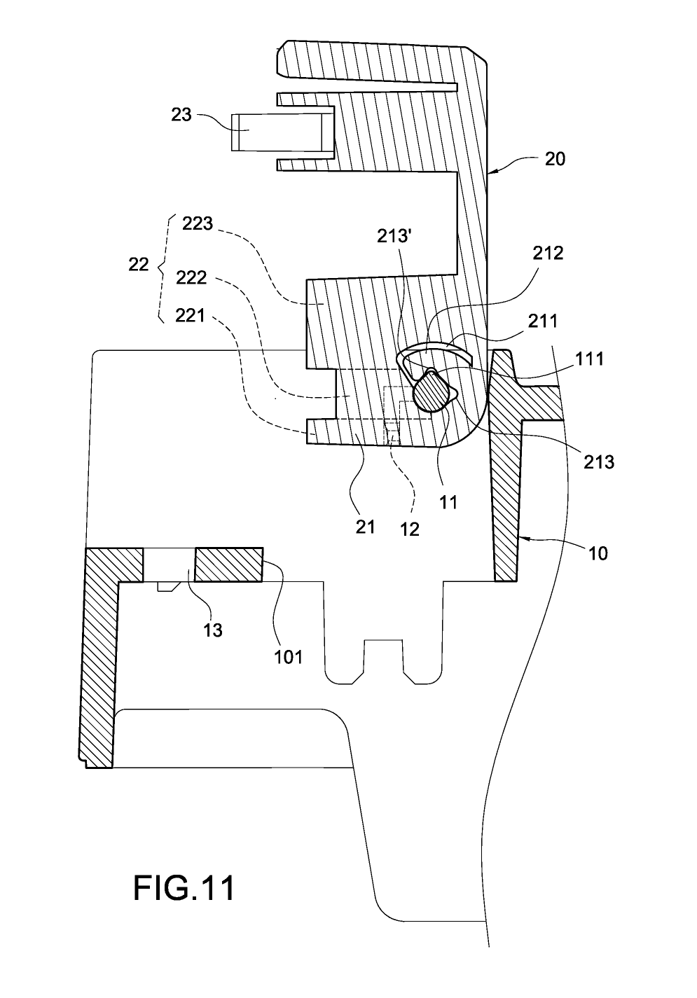

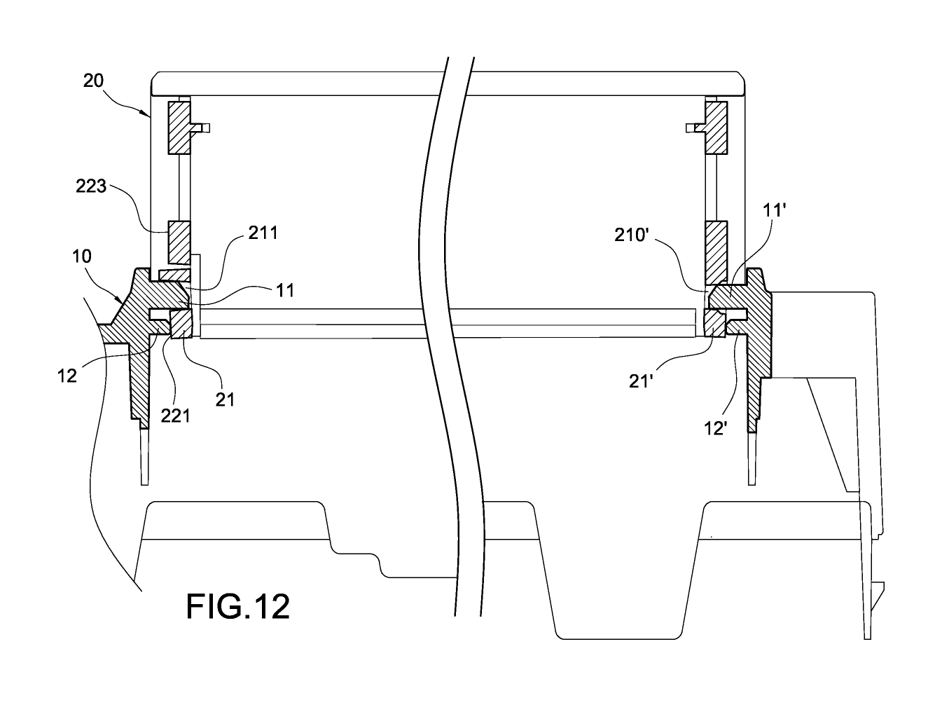

Please refer to FIGS. 11 and 12, which are cross-sectional views showing the rotatable positioning pivot structure 1 of the present invention forms an angle of 90 degrees with respect to the opening 101. The positioning portion 111 of the positioning shaft 11 is located in another positioning slot 213′, and the rib 12 presses onto the outside surface 221 of the abutting portion 22 (indicated by the dotted portion of FIG. 11), so that the elastic piece 21 is subjected to an elastic deformation to abut the outside surface 221. In this way, the frictional force for positioning can be increased. Further, the locations and number of the positioning slots 213, 213′ in the through trough 211 as well as the positioning portion 111 of the positioning shaft 11 can be adjusted and modified according to practical demands.

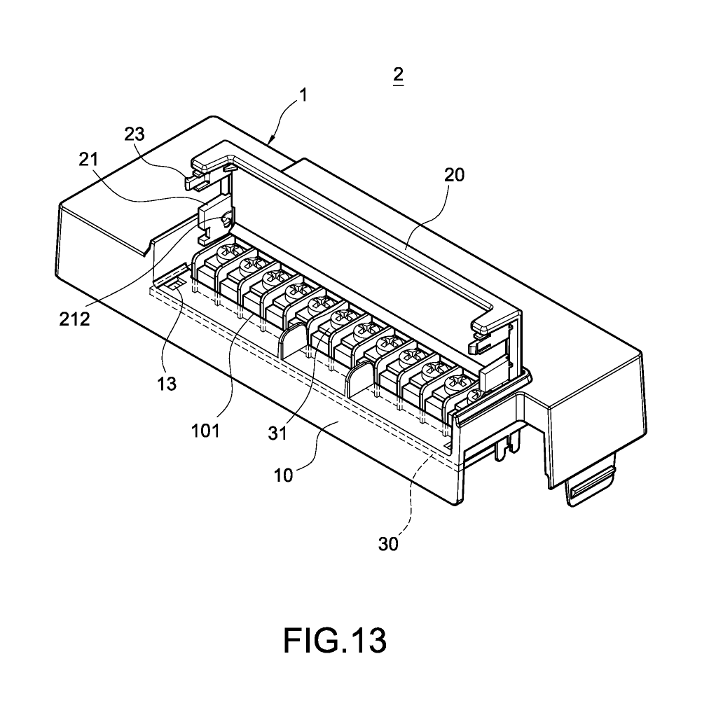

Please refer to FIG. 13, which is a schematic view showing the application of the rotatable positioning pivot structure of the present invention. In the present embodiment, the pivot structure 1 is used in a driver 2. In practice, a circuit board 30 is received in the accommodating space 100 (FIG. 1). The circuit board 30 is provided with a plurality of connecting terminals 31, and these connecting terminals 31 are displayed in the opening 101. When a user intends to connect the connecting terminals 31, the user can open the cover 20, and the cover 20 can be surely positioned to an open state by means of the pivot structure 1 of the present invention. Thus, the cover 20 will not close the opening 101 unintentionally, so that the user can use the driver 2 conveniently.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A driver having a rotatable positioning pivot structure, comprising:
a casing having an accommodating space and an opening in communication with the accommodating space, the casing having a positioning shaft on one side of the opening, the positioning shaft having a positioning portion;
a circuit board received in the accommodating space, the circuit board having a plurality of connecting terminals, the connecting terminals being displayed in the opening; and
a cover movably assembled in the opening of the casing, the cover having an elastic piece on one side thereof, the elastic piece having a through trough, an elastic arm being formed in the through trough, the positioning shaft of the casing penetrating the through trough of the cover and being located inside the elastic arm, an inside of the elastic arm being provided with at least one positioning slot to be engaged with the positioning portion of the positioning shaft.

2. The driver having a rotatable positioning pivot structure according to claim 1, wherein the casing has a rib adjacent to the positioning shaft, the elastic piece of the cover has an abutting portion for abutting the rib.

3. The driver having a rotatable positioning pivot structure according to claim 2, wherein a cross section of the abutting portion is formed into a U shape, and a height of an outside surface of the abutting portion is larger than that of an intermediate surface thereof.

4. The driver having a rotatable positioning pivot structure according to claim 2, wherein a cross section of the rib is formed into an L shape, a distal end of the rib has a protrusion, and the protrusion has a chamfer.

5. The driver having a rotatable positioning pivot structure according to claim 1, wherein a distal end of the positioning shaft has a chamfer.

6. The driver having a rotatable positioning pivot structure according to claim 1, wherein the positioning shaft extends to have a narrowed end, and the positioning portion is formed on a top surface of the narrowed end.

7. The driver having a rotatable positioning pivot structure according to claim 1, wherein the cover further comprises a hook, the casing has a notch corresponding to the hook, and the hook is engaged within the notch.

8. The driver having a rotatable positioning pivot structure according to claim 1, wherein the casing has a shaft on the other side of the opening, the cover has a shaft hole corresponding to the shaft, and the shaft is inserted into the shaft hole.

9. A rotatable positioning pivot structure, including:
a casing having an opening, the casing having a positioning shaft on one side of the opening, the positioning shaft having a positioning portion; and
a cover movably assembled in the opening of the cover, the cover having an elastic piece on its one side, the elastic piece having a through trough, an elastic arm is formed in the through trough, the positioning shaft of the casing penetrating the through trough of the cover and being located inside the elastic arm, an inside of the elastic arm having at least one positioning slot to be engaged with the positioning portion of the positioning shaft.

10. The rotatable positioning pivot structure according to claim 9, wherein the casing has a rib adjacent to the positioning shaft, the elastic piece of the cover has an abutting portion for abutting the rib.

11. The rotatable positioning pivot structure according to claim 10, wherein a cross section of the abutting portion is formed into a U shape, and a height of an outside surface of the abutting portion is larger than that of an intermediate surface thereof.

12. The rotatable positioning pivot structure according to claim 10, wherein a cross section of the rib is formed into an L shape, a distal end of the rib has a protrusion, and the protrusion has a chamfer.

13. The rotatable positioning pivot structure according to claim 9, wherein a distal end of the positioning shaft has a chamfer.

14. The rotatable positioning pivot structure according to claim 9, wherein the positioning shaft extends to have a narrowed end, and the positioning portion is formed on a top surface of the narrowed end.

15. The rotatable positioning pivot structure according to claim 9, wherein the cover further comprises a hook, the casing has a notch corresponding to the hook, and the hook is engaged within the notch.

16. The rotatable positioning pivot structure according to claim 9, wherein the casing has a shaft on the other side of the opening, the cover has a shaft hole corresponding to the shaft, and the shaft is inserted into the shaft hole.
